(19) United States
(12) Patent Application Publication
(10) Pub. No.: US 2017/0010334 A1
(43) Pub. Date: Jan. 12, 2017

(54) GENERAL PURPOSE REMOVAL OF GEOMAGNETIC NOISE

(71) Applicant: Lockheed Martin Corporation, Bethesda, MD (US)

(72) Inventors: James Michael KRAUSE, Saint Michael, MN (US); Arul MANICKAM, Mount Laurel, MD (US)

(73) Assignee: Lockheed Martin Corporation, Bethesda, MD (US)

(21) Appl. No.: 15/003,617

(22) Filed: Jan. 21, 2016

Related U.S. Application Data
(60) Provisional application No. 62/190,218, filed on Jul. 8, 2015.

(51) Int. Cl. G01R 33/00; G01R 33/032

(52) U.S. Cl. CPC G01R 33/0017; G01R 33/032

(57) ABSTRACT

A magnetic sensor system, includes a plurality of magnetic field sensors and a controller. The plurality of magnetic field sensors are arranged in an array, each magnetic field sensor configured to measure a magnetic field at the magnetic field sensor. The controller is configured to receive magnetic field signals from each of the plurality of magnetic field sensors so as have an array of measured magnetic field values corresponding respectively to the magnetic field sensors. The controller is further configured to: transform each of the measured magnetic field values to a common coordinate system to provide an array of transformed magnetic field values; estimate a spatially correlated background noise based on the array of transformed magnetic field values; and subtract the spatially correlated background noise from the transformed magnetic field values to provide noise removed magnetic field values.

### CROSS REFERENCE TO RELATED PATENT APPLICATION

This application claims the benefit of priority from U.S. Provisional Patent Application No. 62/190,218, filed Jul. 8, 2015, which is incorporated herein by reference in its entirety.

The disclosure generally relates to a system for removal of geomagnetic noise.

### BACKGROUND

There are several sources of noise or error that can be relevant to magnetic signal measurements. For extremely slow variations, such as the evolution of the earth's internal magnetic field over time or gradual changes having to do with seasonal shifts in ocean currents, a high-pass filter in the time domain (as opposed to the spatial) can remove the near-DC content. For this reason, the DC content may be left out of the analysis, except for the analysis of coordinate systems in which case a sample of the full unfiltered magnetic field vector is used. Diamond nitrogen-vacancy (DNV) sensors can be used in many magnetometry applications that require very sensitive magnetometers, for example, direction finding and magnetic anomaly detection applications.

Atomic-sized nitrogen-vacancy centers in diamond lattices (See FIG. 1) have been shown to have excellent sensitivity for magnetic field measurement and enable fabrication of small magnetic sensors that can readily replace existing-technology (e.g., Hall-effect) systems and devices. The DNV sensors are maintained in room temperature and atmospheric pressure and can be even used in liquid environments. A green optical source (e.g., a micro-LED) can optically excite NV centers of the DNV sensor and cause emission of fluorescence radiation (e.g., red light) under off-resonant optical excitation. A magnetic field generated, for example, by a microwave coil can probe degenerate triplet spin states (e.g., with mₛ=−1, 0, +1) of the NV centers to split proportional to an external magnetic field projected along the NV axis, resulting in two spin resonance frequencies. The distance between the two spin resonance frequencies is a measure of the strength of the external magnetic field. A photo detector can measure the fluorescence (red light) emitted by the optically excited NV centers. A diamond nitrogen vacancy (DNV) sensor can be used as a very sensitive magnetometer for direction finding and magnetic anomaly detection applications.

### SUMMARY

According to one embodiment, a magnetic sensor system may be provided. The magnetic sensor system, comprising: a plurality of magnetic field sensors arranged in an array, each magnetic field sensor configured to measure a magnetic field at the magnetic field sensor; and a controller configured to receive magnetic field signals from each of the plurality of magnetic field sensors so as have an array of measured magnetic field values corresponding respectively to the magnetic field sensors, wherein the controller is configured to: perform high pass time-domain filtering on the array of measured magnetic field values; transform each of the measured magnetic field values to a common coordinate system to provide an array of transformed magnetic field values; determine that a signal of interest exists in array elements of the array of transformed magnetic field values when the transformed magnetic field value deviates from spatially correlated noise by more than a predetermined threshold; determine one or more regions of interest to be those array elements where the signal of interest exists, where for each region of interest the array elements where the signal of interest exists are adjacent to each other; estimate a spatially correlated background noise based on the array of transformed magnetic field values; and subtract the spatially correlated background noise from the transformed magnetic field values to provide noise removed magnetic field values.

According to one aspect, the magnetic field sensors may be diamond nitrogen vacancy magnetic field sensors.

According to another aspect, the magnetic sensor system may further comprises: a plurality of orientation sensors, each orientation sensor corresponding to a different one of the plurality of magnetic field sensors and configured to measure a Z-direction orientation of a respective magnetic field sensor relative to the common coordinate system.

According to another aspect, the orientation sensor may be a gravity sensor.

According to another aspect, the transforming each of the measured magnetic field values to a common coordinate system may comprise rotating the measured magnetic field values based in part on the measured Z-direction orientation of the magnetic field sensor.

According to another aspect, the rotating the measured magnetic field values may comprise, for each magnetic field sensor, determining a rotation matrix based on the measured Z-direction orientation, an X-direction orientation and a Y-direction orientation of the magnetic field sensor, and taking the product of the rotation matrix with the measured magnetic field value.

According to another aspect, the X-direction orientation may be determined based on subtracting the component of the measured magnetic field value along the Z direction from the measured magnetic field value to provide a difference value, and normalizing the difference value.

According to another aspect, the estimating a spatially correlated background noise may comprise determining a median value of the transformed magnetic field values for all elements of the array of transformed magnetic field values, and setting the spatially correlated background noise as the median value.

According to another aspect, the estimating a spatially correlated background noise may comprise: excluding the one or more regions of interest from the array of transformed magnetic field values to provide a remaining array of transformed magnetic field values; fitting a function to the remaining array of transformed magnetic field values to provide the estimated spatially correlated background noise.

According to another aspect, some of the magnetic field sensors may be outside the one or more regions of interest.

According to another aspect, ≧50% of the magnetic field sensors may be outside the one or more regions of interest.

According to another aspect, the function may be a plane.

According to another aspect, the function may be a quadratic spline.

According to another aspect, the determining one or more regions of interest may comprise determining a core one or more regions of interest, and applying a set closing and convex hulling of the core one or more regions of interest.

According to another aspect, the one or more regions of interest may correspond to one or more unmanned underwater vehicles (UUVs), or ships.

According to another aspect, the array may be a one-dimensional array.

According to another aspect, the array may be a two-dimensional array.

According to another embodiment, a magnetic sensor system may be provided. The magnetic sensor system comprises: a plurality of magnetic field sensors arranged in an array, each magnetic field sensor configured to measure a magnetic field at the magnetic field sensor; and a controller configured to receive magnetic field signals from each of the plurality of magnetic field sensors so as have an array of measured magnetic field values corresponding respectively to the magnetic field sensors, wherein the controller is configured to: transform each of the measured magnetic field values to a common coordinate system to provide an array of transformed magnetic field values; estimate a spatially correlated background noise based on the array of transformed magnetic field values; and subtract the spatially correlated background noise from the transformed magnetic field values to provide noise removed magnetic field values.

According to one aspect, the magnetic field sensors may be diamond nitrogen vacancy magnetic field sensors.

According to another aspect, the magnetic sensor system may further comprise: a plurality of orientation sensors, each orientation sensor corresponding to a different one of the plurality of magnetic field sensors and configured to measure a Z-direction orientation of a respective magnetic field sensor relative to the common coordinate system.

According to another aspect, the orientation sensor may be a gravity sensor.

According to another aspect, the transforming each of the measured magnetic field values to a common coordinate system may comprise rotating the measured magnetic field values based in part on the measured Z-direction orientation of the magnetic field sensor.

According to another aspect, the estimating a spatially correlated background noise may comprise determining a median value of the transformed magnetic field values for all elements of the array of transformed magnetic field values, and setting the spatially correlated background noise as the median value.

According to another aspect, the determining one or more regions of interest may comprise determining a core one or more regions of interest, and applying a set closing and convex hulling of the core one or more regions of interest.

According to another aspect, the array may be a one-dimensional array.

According to another aspect, the array may be a two-dimensional array.

According to another embodiment, a magnetic sensor system may be provided. The magnetic sensor system comprises: a plurality of magnetic field sensors arranged in an array, each magnetic field sensor configured to measure a magnetic field at the magnetic field sensor; and a controller configured to receive magnetic field signals from each of the plurality of magnetic field sensors so as have an array of measured magnetic field values corresponding respectively to the magnetic field sensors, wherein the controller is configured to transform each of the measured magnetic field values to a common coordinate system to provide an array of transformed magnetic field values.

According to one aspect, the magnetic field sensors may be diamond nitrogen vacancy magnetic field sensors.

According to another aspect, the magnetic sensor system may further comprise: a plurality of orientation sensors, each orientation sensor corresponding to a different one of the plurality of magnetic field sensors and configured to measure a Z-direction orientation of a respective magnetic field sensor relative to the common coordinate system.

According to another aspect, the orientation sensor may be a gravity sensor.

According to another aspect, the transforming each of the measured magnetic field values to a common coordinate system may comprise rotating the measured magnetic field values based in part on the measured Z-direction orientation of the magnetic field sensor.

According to another aspect, the rotating the measured magnetic field values may comprise, for each magnetic field sensor, determining a rotation matrix based on the measured Z-direction orientation, an X-direction orientation and a Y-direction orientation of the magnetic field sensor, and taking the product of the rotation matrix with the measured magnetic field value.

According to another aspect, the X-direction orientation may be determined based on subtracting the component of the measured magnetic field value along the Z direction from the measured magnetic field value to provide a difference value, and normalizing the difference value.

According to another embodiment, a magnetic sensor system may be provided. The magnetic sensor system comprises: a plurality of magnetic field sensors arranged in an array, each magnetic field sensor configured to measure a magnetic field at the magnetic field sensor; and a controller configured to receive magnetic field signals from each of the plurality of magnetic field sensors so as have an array of measured magnetic field values corresponding respectively to the magnetic field sensors, wherein the controller is configured to: determine that a signal of interest exists in array elements of the array of measured magnetic field values when the measured magnetic field value deviates from spatially correlated noise by more than a predetermined threshold; determine one or more regions of interest to be those array elements where the signal of interest exists, where for each region of interest the array elements where the signal of interest exists are adjacent to each other; estimate a spatially correlated background noise based on the array of measured magnetic field values; and subtract the spatially correlated background noise from the measured magnetic field values to provide noise removed magnetic field values.

According to another aspect, the magnetic field sensors may be diamond nitrogen vacancy magnetic field sensors.

According to another aspect, the estimating a spatially correlated background noise may comprise determining a median value of the measured magnetic field values for all elements of the array of measured magnetic field values, and setting the spatially correlated background noise as the median value.

According to another aspect, the estimating a spatially correlated background noise may comprise: excluding the one or more regions of interest from the array of measured magnetic field values to provide a remaining array of measured magnetic field values; fitting a function to the remaining array of measured magnetic field values to provide the estimated spatially correlated background noise.

According to another aspect, the function may be a plane.

According to another aspect, the function may be a quadratic spline.

According to another aspect, the determining one or more regions of interest may comprise determining a core one or more regions of interest, and applying a set closing and convex hulling of the core one or more regions of interest.

According to another embodiment, a magnetic sensor system may be provided. The magnetic sensor system comprises: a plurality of magnetic field sensors arranged in an array, each magnetic field sensor configured to measure a magnetic field at the magnetic field sensor; and a controlling unit for: receiving magnetic field signals from each of the plurality of magnetic field sensors so as have an array of measured magnetic field values corresponding respectively to the magnetic field sensors, performing high pass time-domain filtering on the array of measured magnetic field values; transforming each of the measured magnetic field values to a common coordinate system to provide an array of transformed magnetic field values; determining that a signal of interest exists in array elements of the array of transformed magnetic field values when the transformed magnetic field value deviates from spatially correlated noise by more than a predetermined threshold; determining one or more regions of interest to be those array elements where the signal of interest exists, where for each region of interest the array elements where the signal of interest exists are adjacent to each other; estimating a spatially correlated background noise based on the array of transformed magnetic field values; and subtracting the spatially correlated background noise from the transformed magnetic field values to provide noise removed magnetic field values.

According to another embodiment, a method of operating a magnetic sensor system may be provided, the magnetic sensor system having a plurality of magnetic field sensors arranged in an array, each magnetic field sensor configured to measure a magnetic field at the magnetic field sensor. The method comprises: receiving magnetic field signals from each of the plurality of magnetic field sensors so as have an array of measured magnetic field values corresponding respectively to the magnetic field sensors; performing high pass time-domain filtering on the array of measured magnetic field values; transforming each of the measured magnetic field values to a common coordinate system to provide an array of transformed magnetic field values; determining that a signal of interest exists in array elements of the array of transformed magnetic field values when the transformed magnetic field value deviates from spatially correlated noise by more than a predetermined threshold; determining one or more regions of interest to be those array elements where the signal of interest exists, where for each region of interest the array elements where the signal of interest exists are adjacent to each other; estimating a spatially correlated background noise based on the array of transformed magnetic field values; and subtracting the spatially correlated background noise from the transformed magnetic field values to provide noise removed magnetic field values.

According to another embodiment, a method of operating a magnetic sensor system may be provided, the magnetic sensor system having a plurality of magnetic field sensors arranged in an array, each magnetic field sensor configured to measure a magnetic field at the magnetic field sensor. The method comprises: receiving magnetic field signals from each of the plurality of magnetic field sensors so as have an array of measured magnetic field values corresponding respectively to the magnetic field sensors; transforming each of the measured magnetic field values to a common coordinate system to provide an array of transformed magnetic field values; estimating a spatially correlated background noise based on the array of transformed magnetic field values; and subtracting the spatially correlated background noise from the transformed magnetic field values to provide noise removed magnetic field values.

According to another embodiment, a method of operating a magnetic sensor system, the magnetic sensor system having a plurality of magnetic field sensors arranged in an array, each magnetic field sensor configured to measure a magnetic field at the magnetic field sensor. The method may comprise: receiving magnetic field signals from each of the plurality of magnetic field sensors so as have an array of measured magnetic field values corresponding respectively to the magnetic field sensors; and transforming each of the measured magnetic field values to a common coordinate system to provide an array of transformed magnetic field values.

According to another embodiment, a method of operating a magnetic sensor system may be provided, the magnetic sensor system having a plurality of magnetic field sensors arranged in an array, each magnetic field sensor configured to measure a magnetic field at the magnetic field sensor. The method comprises: receiving magnetic field signals from each of the plurality of magnetic field sensors so as have an array of measured magnetic field values corresponding respectively to the magnetic field sensors; determining that a signal of interest exists in array elements of the array of measured magnetic field values when the measured magnetic field value deviates from spatially correlated noise by more than a predetermined threshold; determining one or more regions of interest to be those array elements where the signal of interest exists, where for each region of interest the array elements where the signal of interest exists are adjacent to each other; estimating a spatially correlated background noise based on the array of measured magnetic field values; and subtracting the spatially correlated background noise from the measured magnetic field values to provide noise removed magnetic field values.

### BRIEF DESCRIPTION OF THE DRAWINGS

FIG. 1 illustrates a nitrogen-vacancy center in a diamond lattice.

FIG. 2 illustrates a geomagnetic noise model compared with empirical noise data.

FIG. 3 is a graph illustrating a signal of interest due to a distortion in the magnetic field in the Z-direction as measured by a single magnetic sensor.

FIGS. 4A-4C are graphs illustrating the signal of interest due to a distortion in the magnetic field in the Z-direction as measured by a two-dimensional magnetic sensor array for times of 1100, 1115 and 1120 seconds, respectively.

FIG. 5 is a schematic illustrating a magnetic sensor array system according to an embodiment of the invention.

FIGS. 6A and 6B respectively illustrate a common coordinate system and a coordinate system corresponding to one of the magnetic sensors of the array.

FIG. 7 is a schematic illustrates an orientation sensor attached to a magnetic field sensor according to an embodiment of the invention.

FIGS. 8A-8C are graphs illustrating a magnetic field measurement component along the X-direction, Y-direction and Z-direction, respectively, at a time of 500 seconds for a two-dimensional array of magnetic field sensors in the case of a single unmanned underwater vehicle (UUV).

FIGS. 8D-8F are graphs illustrating a magnetic field measurement component along the X-direction, Y-direction and Z-direction, respectively, at a time of 1000 seconds for a two-dimensional array of magnetic field sensors in the case of a single UUV.

FIGS. 8G-8I are graphs illustrating a magnetic field measurement component along the X-direction, Y-direction and Z-direction, respectively, at a time of 1500 seconds for a two-dimensional array of magnetic field sensors in the case of a single UUV.

FIGS. 9A-9C are graphs illustrating a magnetic field measurement component along the X-direction, Y-direction and Z-direction, respectively, at a time of 500 seconds for a two-dimensional array of magnetic field sensors in the case of two UUVs.

FIGS. 9D-9F are graphs illustrating a magnetic field measurement component along the X-direction, Y-direction and Z-direction, respectively, at a time of 1000 seconds for a two-dimensional array of magnetic field sensors in the case of two UUVs.

FIGS. 9G-9I are graphs illustrating a magnetic field measurement component along the X-direction, Y-direction and Z-direction, respectively, at a time of 1500 seconds for a two-dimensional array of magnetic field sensors in the case of two UUVs.

FIG. 10A is a graph illustrating the X-direction component of the noise free and measured magnetic fields as a function of time for a single magnetic field sensor measurement.

FIG. 10B is a graph illustrating the noise free and reconstructed X-direction component of the magnetic field as a function of time for a single magnetic field sensor measurement as a function of time, where the noise has been removed by a median subtraction algorithm.

FIG. 10C is a graph illustrating the difference in the noise free and reconstructed X-direction component of the magnetic fields of FIG. 10B.

FIGS. 11A-11C are graphs illustrating the magnetic field for an array of sensors including the signal of interest in the X-direction for the array at times of 500, 1000 and 1500 seconds, respectively.

FIGS. 12A-12C are graphs illustrating, in the X-direction, a region of interest and a expanded region of interest as a results of set closing and convex hulling, at respective times of 500, 1000 and 1500 seconds for a single UUV.

FIGS. 13A-13C are graphs illustrating a fit to a plane of the X-direction component of magnetic field measurement data with the region of interest data removed for a two-dimensional array of magnetic field sensors at times of 500, 1000 and 1500 seconds, respectively.

FIG. 14A is a graph illustrating the X-direction component of noise free and measured magnetic fields as a function of time for a single magnetic field sensor measurement.

FIG. 14B is a graph illustrating the noise free and reconstructed X-direction component of the magnetic field as a function of time for a single magnetic field sensor measurement as a function of time, where the noise has been removed using noise fit to a plane.

FIG. 14C is a graph illustrating the difference in the noise free and reconstructed X-direction component of the magnetic field of FIG. 14B.

FIGS. 15A-15C are graphs illustrating a fit to a quadratic spline of the X-direction component of magnetic field measurement data with the region of interest data removed for a two-dimensional array of magnetic field sensors at times of 500, 1000 and 1500 seconds, respectively.

FIG. 16A is a graph illustrating the X-direction component of noise free and measured magnetic fields as a function of time for a single magnetic field sensor measurement.

FIG. 16B is a graph illustrating the noise free and reconstructed X-direction component of the magnetic field as a function of time for a single magnetic field sensor measurement as a function of time, where the noise has been removed using noise fit to a quadratic spline.

FIG. 16C is a graph illustrating the difference in the noise free and reconstructed X-direction component of the magnetic field of FIG. 16B.

FIGS. 17A-17C are graphs illustrating, in the X-direction, a region of interest and a expanded region of interest as a results of set closing and convex hulling, at respective times of 500, 1000, and 1500 seconds for two UUVs.

FIGS. 18A-18C are graphs illustrating a fit to a quadratic spline of the X-direction component of magnetic field measurement data with the region of interest data removed for a two-dimensional array of magnetic field sensors at times of 500, 1000 and 1500 seconds, respectively, for two UUVs.

FIG. 19A is a graph illustrating X-direction component of noise free and measured magnetic fields as a function of time for a single magnetic field sensor measurement for two UUVs.

FIG. 19B is a graph illustrating the noise free and reconstructed X-direction component of the magnetic field as a function of time for a single magnetic field sensor measurement as a function of time, where the noise has been removed using noise fit to a quadratic spline.

FIG. 19C is a graph illustrating the difference in the noise free and reconstructed X-direction component of the magnetic field of FIG. 19B.

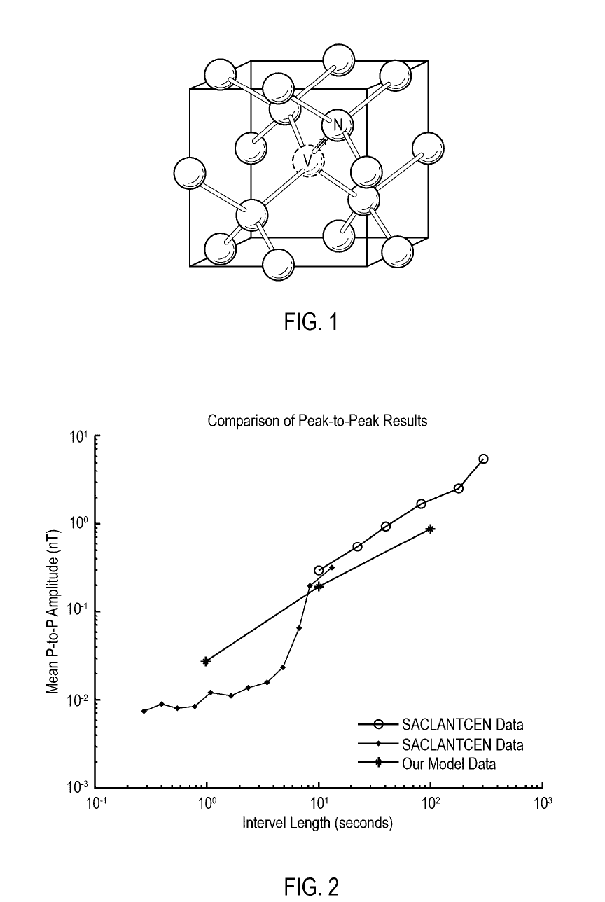

### DETAILED DESCRIPTION

Various aspects of the subject technology provide methods and systems for general purpose removal of geomagnetic noise. The subject solution combines the use of an array (e.g., 1-D or 2-D) of highly sensitive vector magnetic sensors with proper transformation means and signal processing to separate the broadly-spatially-correlated Pc and Pi noise from the local anomalies that affect fewer sensors of a spatially distributed array of DNV sensors. The vector magnetic sensors of the subject technology are large enough and spaced densely enough such that the magnetic signal of interest (SOI) is detected by at least one sensor but is below the target noise floor for many of the other sensors. The proper transformation means can achieve transforming the sensor measurements to a common coordinate system by transforming each element of an array of measured magnetic field values to provide an array of transformed magnetic field values. The signal processing includes signal processing of the spatially distributed array of sensors.

### Geomagnetic Noise

Geomagnetic noise that is of considerable significance is that due to the solar wind impinging on the exoatmosphere. This noise can be decomposed into diurnal variations (slow daily variations due to the orientation of the earth relative to the sun) and what are termed “Pc and Pi” noise. The Pc and Pi noise are the most problematic in many potential applications, as they vary in time scales that are similar to the magnetic signals that one may wish to measure (signals resulting from some object in motion relative to a magnetic sensor, either because the object is moving and the sensor is stationary, or because the object is stationary and the sensor is being moved, or some combination). It is thought that the Pc and Pi noise, together, span the frequency range of 0.01 Hz and 5 Hz, with a spectrum shape proportional to 1/f (f is frequency) in this band.

The nature of the Pc and Pi noise may be investigated by comparing generated model Pc and Pi noise to that of empirical data. This model Pc and Pi noise may be generated, for example, by passing white Gaussian noise through a linear filter with this shape and steep rolloff above and below this passband. For amplitude, empirical data was used from [J. Watermann and J. Lam, “Distributions of Magnetic Field Variations, Differences, and Residuals,” SACLANTCEN, San Batrolomeo, IT, Tech. Rep. SR-304, February 1999 (“SACLANTCEN”)], which measures peak-to-peak values over time windows of different lengths, averaged over months. The noise amplitude of the model data is adjusted to have comparable peak-to-peak statistics. The comparison is shown in FIG. 2, where the geomagnetic noise model compares well with empirical data.

The SACLANTCEN paper also suggests that the geomagnetic noise is spatially highly correlated over tens of kilometers. Other sources discuss the Pc and Pi noise as originating at an altitude of about 100 km, affirming that it is reasonable to expect high correlation over distances greater than 10 km when measured on the earth surface or undersea.

### Signal of Interest

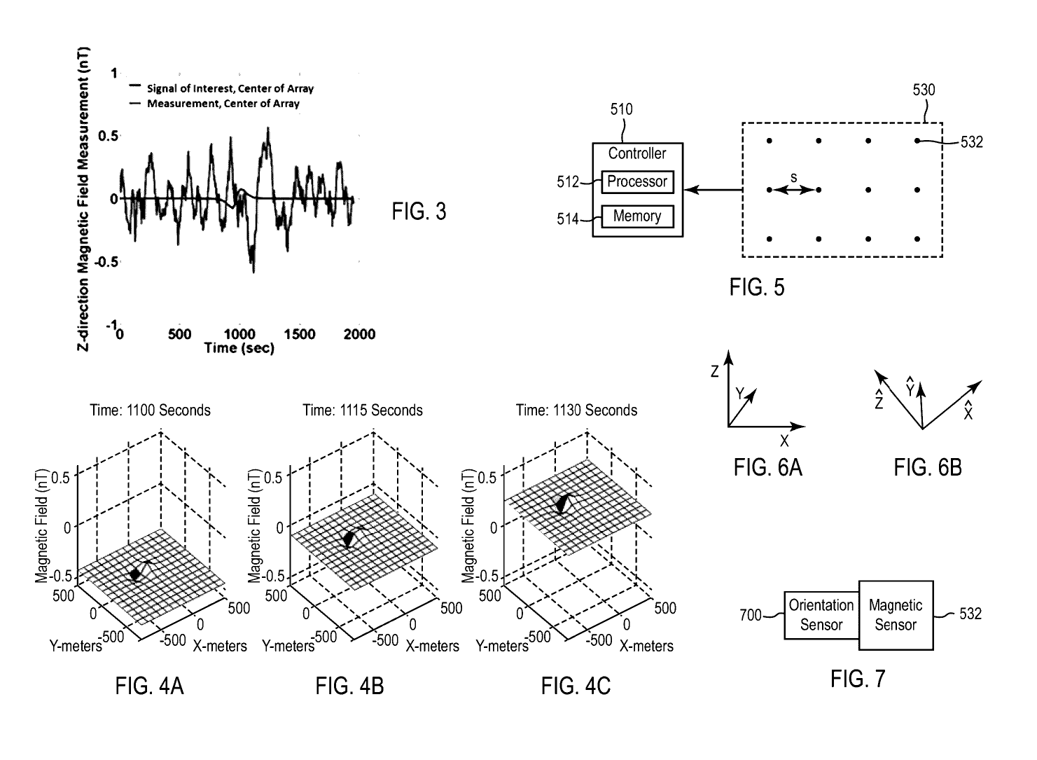

FIG. 3 illustrates a signal of interest due to a distortion in the magnetic field in the Z-direction by an unmanned underwater vehicle (UUV) for magnetic field over time as measured by a single magnetic sensor. FIG. 3 illustrates the signal of interest without noise and a measurement of the signal of interest including noise. As can be seen, the signal of interest is overwhelmed by the noise.

FIGS. 4A-4C illustrate the signal of interest due to a distortion in the magnetic field in the Z-direction by an unmanned underwater vehicle (UUV) for magnetic field at three different times as measured by a two-dimensional array of sensors, to provide an array of measured magnetic field values, on the sea floor. As can be seen, the noise appears fairly flat over the area shown, with the excepton of a hill-valley pair which is the signal of interest (magnetic field distortion from presence of a ferrous metal object, the UUV). The array used for the dataset is a 31-by-31 sensor array spaced at 100 m, such that the center is the 16 (row), 16 (column) sensor.

### Removal of Geomagnetic Noise

In some aspects of the present technology, methods and configurations for general purpose removal of geomagnetic noise are disclosed. The subject technology combines precision vector magnetometers with a large and dense array of sensors, a means of establishing a common coordinate system, high pass time domain filtering, and noise removal exploiting spatial correlation of noise. The large and dense array of sensors is sufficiently large such that many sensors are unaffected by a signal of interest and spaced closely enough such that the signal of interest is detected by at least one sensor when the signal is present. In some implementations, the sensor array may include 1-D (one-dimensional) or 2-D (two-dimensional) array of many precision vector magnetometers. High pass time-domain filtering can remove very slow variations on the order of many hours or longer.

For ease of description, let S be the signal defined as the local magnetic field variation of interest, which is to be measured, and let F be the interest floor chosen to be a value lower than the amplitude of S to be used in the definition of signals that are too small to be of interest. Let Rmax be the maximum influence region of S, defined as maximum size and shape of the region (1-D or 2-D) in which the amplitude of S may be greater than F. Let N be the vector environmental noise for which the time variations of the noise may be large compared to S, but at each time sample are spatially correlated such that the variation is much less than F over a distance more than twice the diameter of Rmax. Using the above definitions, the vector magnetic sensor of the subject technology are of high precision relative to F such that the sensor noise is negligible as compared to F. The array (1-D or 2-D) of these sensors is dense enough such that when the variation of interest is present, S is greater than F for at least one sensor and large enough relative to Rmax such that for most of the sensors, S is less than F. The means of establishing a common coordinate system can measure the orientation of the sensors relative to the local earth coordinate system so as to achieve a common coordinate system among the sensors. A spatial-domain common-mode rejection algorithm (CMRA) processes each time sample of the array measurements and produces an array of values preserving local variations greater than F, while reducing residual errors from N to amplitude below F.

In one or more implementations, the magnetic sensor is a DNV sensor. The means of measurement of the orientation of the sensor can be the measurement of the earth's local magnetic field as one reference direction, and an inclinometer (gravity) vector measurement as a second reference direction. In some aspects, the CMRA includes subtraction of the median value of the sensor array at each point in time. The CMRA can further include the combination of the identification of a region of interest where S may be present, a noise estimation using the measurements outside of the region of interest, and subtraction of the estimated noise. The identification of a region of interest may be performed either by using the difference of the measured value from the median value exceeding a chosen threshold, or the spatial gradient of the measured value exceeding a chosen threshold. The noise estimation can be performed by fitting the measurements with a curve such as a constant (e.g., the average of the measurements), a line (e.g., in the case of a 1-D array), a plane (e.g., in the case of a 2-D array), or a spline. In some implementations, the noise estimation can include a Kriging approach to estimate the noise in the region of interest from the measured values outside of the region of interest.

### Magnetic Sensor Array System

FIG. 5 illustrates a magnetic sensor array system 500 according to an embodiment of the invention. The system includes a controller 510 and a magnetic sensor array 530, which includes a number of magnetic sensors 532. The spacing being adjacent sensors 532 may be s, for example. While FIG. 5 illustrates the magnetic sensors 532 to be arranged in a two-dimensional array, the magnetic sensors 532 may be arranged in a one-dimensional array or in some other dimension. Further, while FIG. 5 illustrates a 4 by 3 array of sensors 532 for simplicity, in general the array may be much larger, or may be smaller.

The controller 510 receives magnetic field signals from each of the magnetic sensors 532, where the magnetic field signals are indicative of the magnetic field measured at each of the magnetic sensors 532. Thus, the controller 510 receives an array of magnetic field values. The controller 510 may include a processor 512 and a memory 514. The magnetic field signals received by the controller 510 may be stored in the memory 514 as data. The memory 514 may further store instructions which are executed by the processor to allow the controller 510 to perform various data processing operations, such as establishing a common coordinate system, high pass time domain filtering, and noise removal exploiting spatially coordinated noise, as discussed further below. The memory 514 may include a non-transitory computer readable medium to store the instructions and data.

While FIG. 5 illustrates a single processor 512 and a single memory 514, in general the controller 510 may include more than one processor 512 to perform various functions, and may include more than one memory. Further the controller 510 may include subcontrollers arranged in a distributed manner.

The sensors 532 may be DNV sensors, for example, or other magnetic sensors such as Hall effect sensors.

### Common Coordinate System for Magnetic Sensors

The magnetic fields measured by each of the magnetic sensors may be transformed to a common coordinate system which is common to all of the magnetic sensors. Thus, the measured magnetic field values are transformed to an array of transformed magnetic field values. FIGS. 6A and 6B illustrate a common coordinate system, and coordinate system corresponding to one of the magnetic sensors, respectively. As an alternative to transforming to a common coordinate system, the sensors may be arranged such that they are fixed relative to each other such that they are initially in a common coordinate system. This could be accomplished by fixing the sensors in a rigid material, for example.

In the coordinate system, the Z axis is considered to be “down,” that is, the direction of the gravity vector. In general, while there may be extremely slight variations in the direction of the gravity vector for the different elements of the sensor array, these variations will be extremely small in comparison to the gravity sensor errors introduced for the sensor error model, and thus can be considered included in the sensor error model. The X axis is considered to be perpendicular to the Z axis such that the local magnetic north vector is in the X-Z plane. Y is considered to be perpendicular to X and Z thus providing a right-hand coordinate system, where Y is pointed nearly east.

FIG. 7 illustrates an orientation sensor 700 attached to a magnetic field sensor 532. Each of the magnetic field sensor 532 may have a corresponding orientation sensor 700, which measures the orientation of magnetic field sensor 532 relative to one or more directions, such as the Z-direction, for the common coordinate system. The orientation sensor 700 aids in achieving a common coordinate system for the data from all of the sensors 532. The orientation sensor 700 may be a gravity sensor, which is affixed to a corresponding one of the sensors 532. The orientation sensor 700 is aligned with its corresponding sensor 532 so as to be in a same coordinate system.

It is assumed that the sensors 532 are initially scattered at random orientations. Then, any vector V in the X, Y, Z general coordinate system will be measured in the sensor coordinate system of a sensor as V_{M}=RV where R is a unitary rotation matrix for the particular sensor 532. In general, for the sensor arranged in the i,j position in the array, R could be designated as R^{i,j} to denote the rotation matrix associated with the sensor in the i, j position since it will be different for each i, j. In discussing a single sensor the i, j notation may be omitted for simplicity.

The columns of R are the directions the X, Y, and Z components appear in the sensor coordinate system. To convert the sensor measurements to the X, Y, Z common coordinate system, one simply correlates with R. That is, V=R^{T}V_{M}, wherein, R^{T}R=I, the identity matrix.

Converting the magnetic measurements of each magnetic sensor 532 to a common coordinate system is as follows. For each sensor, measure 11 as a coordinate system calibration step. This may be achieved partly by using a gravity sensor as the orientation sensor 700, for example. Alternatively, the orientation may be taken based on detection of the orientation of the stars. Then take the product of magnetic measurements with the transpose of the rotation matrix, R^{T}, to place the magnetic measurements in the X, Y, Z common coordinate system.

The rotation matrix R may be estimated as follows. As stated, the third column of R is the vector direction in a sensor coordinate system that would result from an input in the Z direction. The estimate of the Z direction in sensor coordinates may be denoted as \hat{Z}, thus the estimated R, denoted \hat{R}, has as its third column, \hat{Z}. Likewise, the first and second columns of \hat{R} may be denoted as \hat{X} and Ŷ respectively. Thus, determining the estimated \hat{R} is performed by estimating the columns of \hat{R}, being \hat{X}, Ŷ and \hat{Z}.

The \hat{Z} value may be simply taken as the measurement of Z from the orientation sensor 700, which may be a gravity sensor. The measurement of Z from a gravity sensor will be the true value of Z plus a rotation error in the sensor. A reasonable bound on a rotation error for existing cost-effective gravity sensors is 0.01 degrees.

The \hat{X} value may be calculated by taking the magnetic measurement of a sensor 532, which is dominated by the earth's local magnetic field, and removing the component in the \hat{Z} direction and then normalizing, using routine linear algebra. This will closely approximate X, with minor errors due to the very small variations in magnetic north over the array, and with small geomagnetic noise and magnetic sensor noise, and the errors in \hat{Z}. Ŷ may then be calculated with a standard cross-product calculation between \hat{X} and \hat{Z}.

The accuracy of the transformation of the magnetic field measurement to a common coordinate system may be estimated as follows.

As an initial step, all of the sensors are independently randomly orientated, with the following process: For each sensor: (1) generate an axis of rotation by selecting a random vector with a uniform distribution over the unit sphere, (2) generate an angle of rotation by selecting a random angle uniformly from

$$[ - \frac{π}{3} radians , \frac{π}{3} radians ] ,$$

and (3) create a random rotation matrix for the sensor based on the selected axis of rotation and angle of rotation by using well-known linear algebra techniques, such as the Rodrigues' rotation formula, for example. This random rotation provides the true value for R^{i,j} for each i,j sensor. The rotation is then applied to the magnetic field dataset of the sensor, producing the dataset in the non-aligned individual sensor coordinates.

For each magnetic sensor, R^{i,j} for each i, j was calculated separately, with the following imperfection including: (1) a gravity sensor rotational error of about 0.01 degrees, unique for each sensor, where the error was simulated by: (a) randomly picking a rotation error from a uniform distribution over [−0.01 degrees, 0.01 degrees], (b) rotating a unit vector lined up with the Z-Axis towards the Y-Axis by the selected rotation error to form Z′, (c) randomly picking a second rotation angle uniformly from [0, 2π], and (d) rotating Z′ about the original Z-axis by the selected second rotation angle, and (2) a single time sample of the modeled geomagnetic noise and magnetic sensor noise. The single time sample was provided such that the value of the earth's magnetic field (magnetic north) was based on a location in the ocean in the vicinity of New York City. At this latitude, magnetic north had a significant inclination. In X, Y, Z coordinates, the earth magnetic field vector used was

$$[ \begin{matrix}22.7 \\ 0 \\ 44.055\end{matrix} ]$$

micro Tesla.

For each sensor, the transpose of R^{i,j} was applied to place the measurements in the common X, Y, Z coordinate system. That is the data used below for all of the common mode rejection algorithms. Further, for the common mode rejection algorithms that follow, a (time/freq domain) high-pass filter is applied to the array of measured magnetic field values remove variations that are very slow (e.g. nearly constant over hours) and therefore the large magnetic north component is absent. Here, for coordinate system calibration, the unfiltered magnetic measurement is used because magnetic north is of interest in establishing the coordinates.

As a final view of the accuracy of the common coordinates, the imperfection of the inverse was measured by taking E=[R^{i,j}]^{T}[R^{i,j}]−1 for all i, j. The induced 2-norm of E (maximum singular value) across the array is typically around 0.0004, which is very small compared to 1. Hence, the approximate R inverse is quite accurate.

In summary, applying random sensor rotations and the approximate correction to a common coordinate system, the true high-passed (DC removed) magnetic field data D_{T}^{i,j}(t) in the X, Y, Z coordinate system is provided and is then converted to sensor measurements, and then the sensor measurements are transformed (with imperfections) to a common coordinate system dataset, which in the true X, Y, Z coordinate system is D^{i,j}(t)=[R^{i,j}]^{T}[R^{i,j}]D_{T}^{i,j}(t).

### Common Mode Rejection Algorithm to Recover Signal of Interest

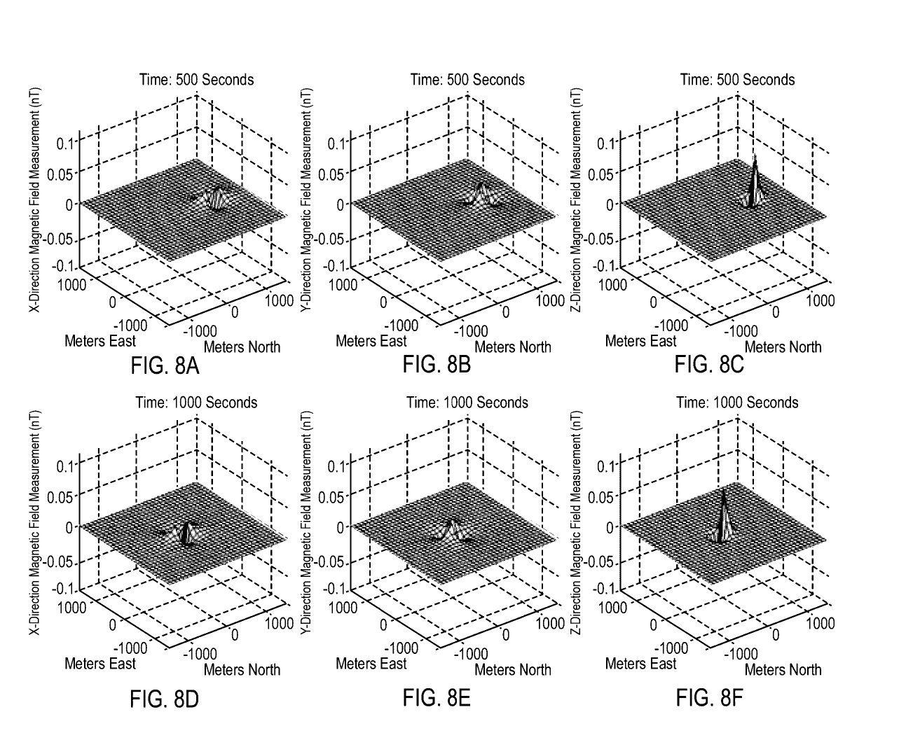

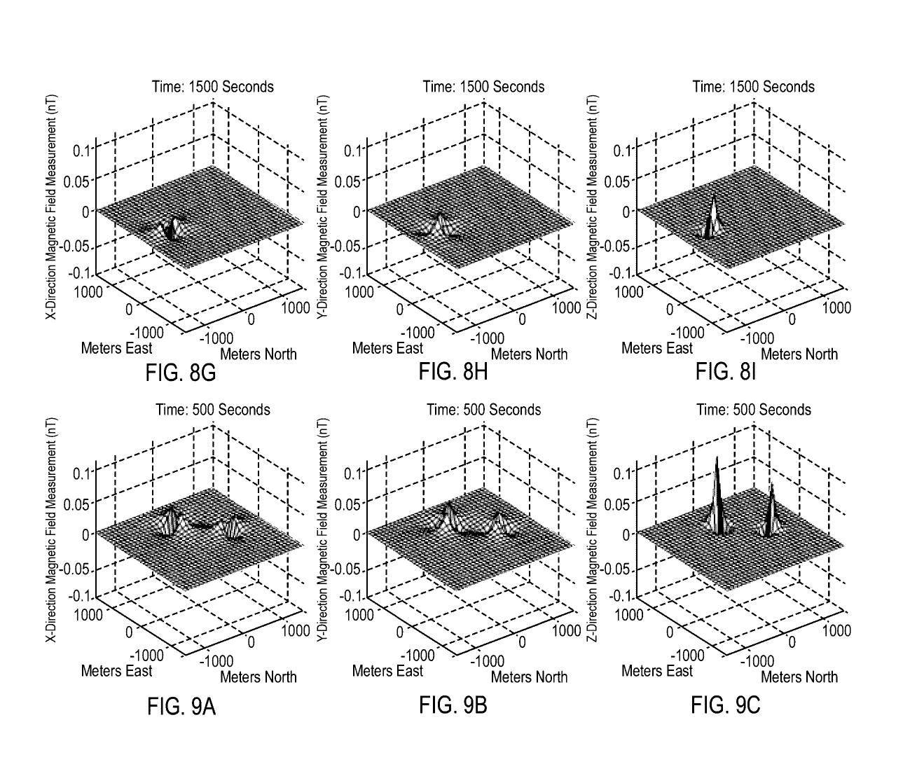

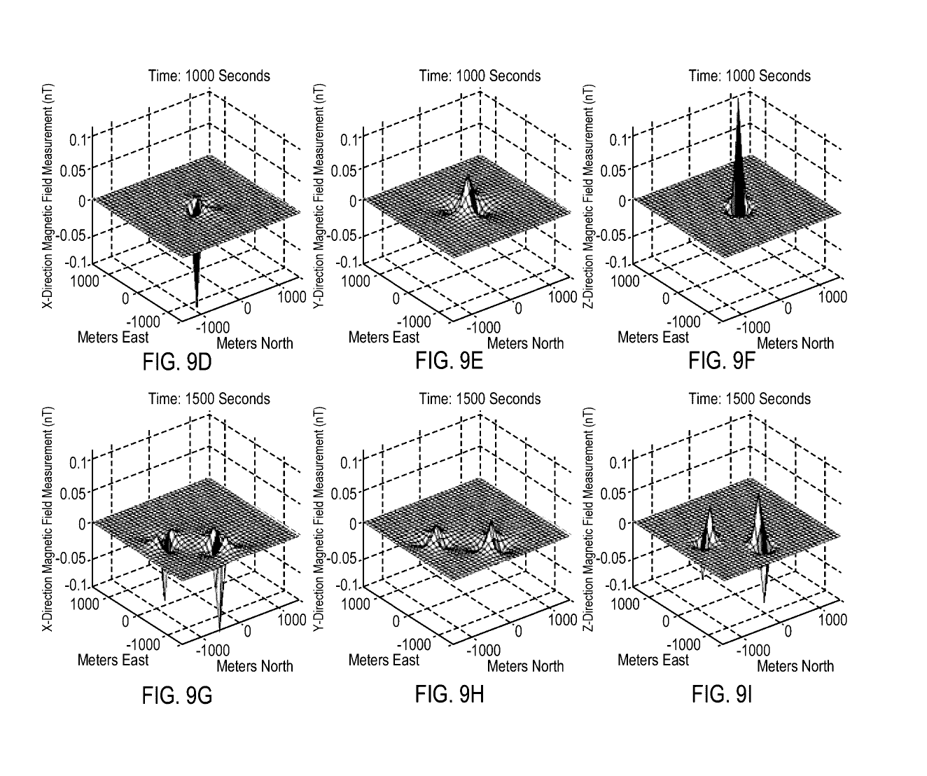

FIGS. 8A-8I illustrate the array of measured magnetic field values including the magnetic signal of interest without noise in a scenario where one UUV is travelling past the array of sensors, and FIGS. 9A-9I illustrate the signal of interest with two UUVs passing at different depths and in different directions. FIGS. 8A-8C illustrate the magnetic field measurement component along the X-direction, Y-direction and Z-direction, respectively, at a time of 500 seconds. FIGS. 8D-8F illustrate the magnetic field measurement component along the X-direction, Y-direction and Z-direction, respectively, at a time of 1000 seconds. FIGS. 8G-8I illustrate the magnetic field measurement component along the X-direction, Y-direction and Z-direction, respectively, at a time of 1500 seconds. FIGS. 9A-9I correspond to FIGS. 8A-8I, respectively, but for the case of two UUVs. These are the signals of interest to be recovered when all sensor imperfections and noise are included.

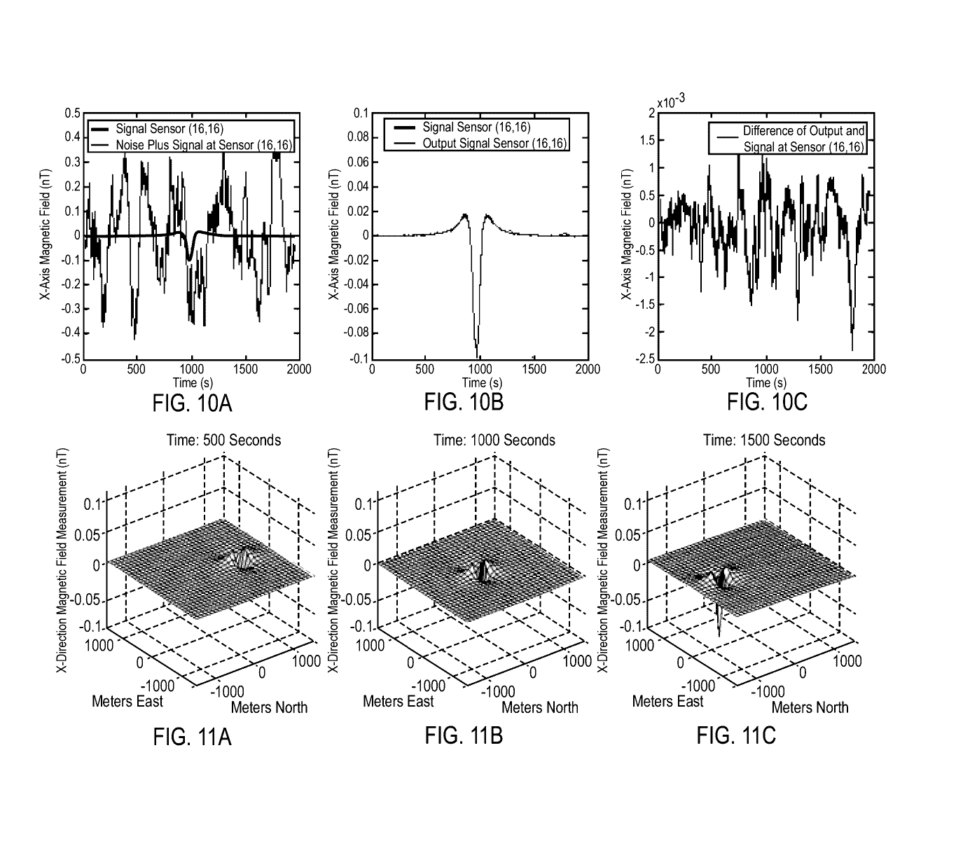

In recovering the signal of interest, first all sources of noise and sensor error are included in the magnetic field measurement data set in a manner as discussed above. The algorithms to produce a common coordinate system are employed, and various CMRA are then applied. To visualize the effectiveness of the results, the results at a single sensor as time evolves is shown where the left plot shows the measurement at that sensor, and the noise-free signal of interest (see FIG. 10A, for example). It is clear from the plot that the signal is not visible in the measurement without the geomagnetic noise removal. The middle plot (see FIG. 10B, for example) shows the result at the same sensor, which plot shows the perfect noise-free signal of interest, and the output of the CMRA after noise removal. For all of the CMRA algorithms, the reconstruction looks nearly perfect in the center plot. The right plot (see FIG. 10C, for example), however shows the difference in the two lines (noise free and reconstructed) of the center plot, on a different scale, to show that the reconstruction is not actually perfect. For ease of illustration, only the results of the magnetic field along the X-direction is shown in the left, middle and right plots, where the magnetic field of course may be reconstructed additionally in the Y-direction and the Z-direction. The actual results in practice would depend on the specific noise levels and other errors.

### Median Subtraction Algorithm

According to the Median Subtraction Algorithm, the median value of the magnetic field for all of the sensors of the array is determined for each of the X, Y, and Z coordinates separately, and the median value is then subtracted from the magnetic field dataset. Thus, the median value of the magnetic field value is taken as an estimate of the spatially correlated background noise and subtracted from the transformed magnetic field values to provide noise removed magnetic field values. Because the noise is spatially highly correlated and because the signal of interest is significant in less than half of the array, the median value is a reasonable measurement of the geomagnetic noise. FIGS. 10A-10C show the results for the Median Subtraction approach, where FIG. 10A shows the magnetic measurement at one of the sensors, and the noise-free signal of interest, over time, FIG. 10B shows the result at the same sensor after noise removal, and the noise-free signal of interest, and FIG. 10C shows the difference in the two lines (noise free and reconstructed) of FIG. 10B, on a different scale. FIGS. 11A-11C shows the magnetic field including the signal of interest in the X-direction for the array at times of 500, 1000 and 1500 seconds, respectively, which demonstrates an excellent fit when compared to the noise free signal shown in FIGS. 8A, 8D and 8G, respectively.

### Spatially Correlated Noise in Region of Interest

The spatially correlated noise in the region of interest, where the region of interest provides the signal of interest, may be estimated, and subtracted from the magnetic field measurement in the region of interest. There are multiple approaches to estimating the spatially correlated noise, and examples are provided below. In general, the spacing of the sensors and the size of the array of sensors is such that some of the sensors 532 are not in the region of interest. The fraction of the sensors which are outside the region of interest may be ≧50%, for example.

For each of the examples, the following steps are taken. First, a “region of interest” is established, where the region of interest are those magnetic sensors where there appears to be a signal of interest because the magnetic measurements show local deviation from the spatially correlated noise by more than a predetermined threshold. In the region of interest the array elements where the signal of interest exists are adjacent to each other. Second, the region of interest is excluded from the region where the rest of the measurement are performed (the remaining magnetic sensors which are not part of the region of interest) to provide a remaining array of transformed magnetic field values, and the rest of the measurements are used to estimate the geomagnetic noise. Finally, the estimated geomagnetic noise is subtracted from the entire region (the region of interest plus the remaining region) covered by the magnetic sensor array (all of the magnetic sensors) including the signal of interest.

One method for identifying the signal of interest is as follows. The median measured magnetic field is subtracted across the array from each magnetic sensor, and then a predetermined amplitude threshold (such as 0.01 nT in these examples) is applied. Any magnetic sensor values above the threshold are assumed to be signals of interest in the region of interest.

Optionally, the region of interest may be expanded slightly using expansion techniques. Because magnetic field variations do not change abruptly, the region of interest may be expanded. For example, the region of interest may be expanded using a set closing algorithm, based on dilation followed by erosion, using standard morphological image processing techniques and then taking the convex hull of the resulting region.

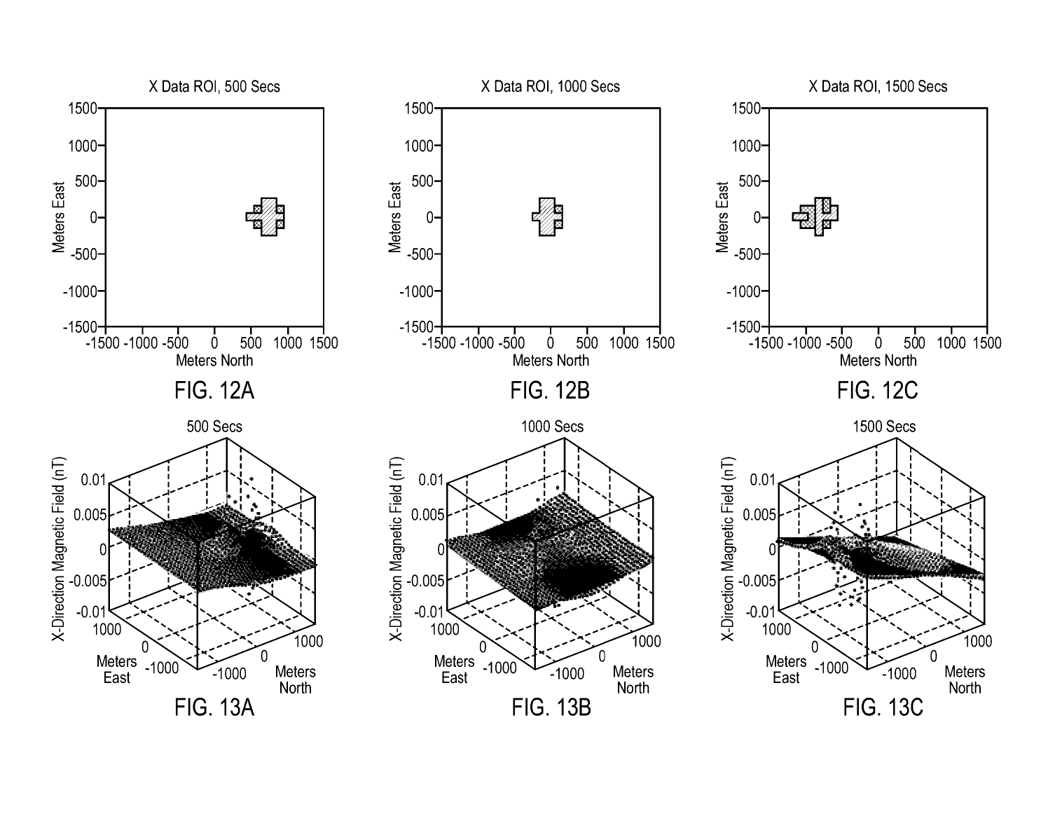

FIGS. 12A-12C shows the resulting regions of interest in an example for the magnetic field component in the X-direction at 500, 1000, and 1500 seconds, respectively. In each case, the lighter color region is the “core” region of interest, i.e. the values for which the measurements deviate from the array median enough to exceed the threshold. The darker color regions are the additional sensors that are included in the region of interest as a result of set closing and convex hulling of the region. As an alternative to set closing and convex hulling of the region, the region of interest could be expanded by taking the union of the regions according to the magnetic field components in the X-direction, Y-direction and Z-direction, or, alternatively use the 2-norm of the vector value in the thresholding step.

Once the region of interest is identified, it is removed, and then the rest of the data is fit, such as, for example, by fitting to a plane, or fitting to a quadratic spline. This gives a geomagnetic noise estimate that can be used in the entire region including the identified region of interest. As an alternative to fitting to a plane or aquadratic spline, a Kriging technique could be applied to the data with region of interest removed, to produce an estimate of the noise in the region of interest.

FIGS. 13A, 13B and 13C illustrate a fit of a plane to the data for the magnetic field component in the X-direction, where FIGS. 13A, 13B and 13C correspond to times of 500, 1000 and 1500 seconds. In FIGS. 13A, 13B and 13C, the fit plane is the meshed sheet, and the specific sensor measurements are the dots. The dots obscure the plane to some extent, but in all cases the plane is a reasonably good fit. There are a few points near the region of interest that are not as close to the plane. This is because they are affected by the signal of interest but at a level below the thresholding, and are also outside of the set closing and convex hulling which increases the region of interest. For this example, there are enough other sensor elements that the noise estimation is effective in spite of those exceptional sensor measurements. A greater dilation of the region of interest could be employed, but it is not necessary in this example.

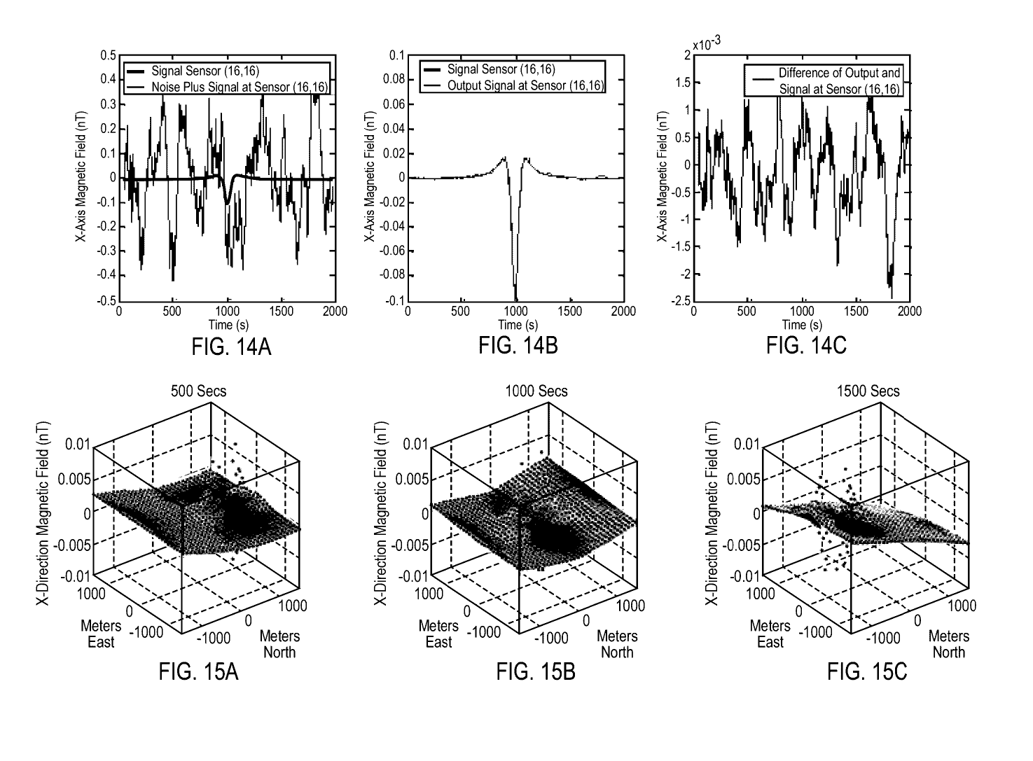

FIGS. 14A, 14B and 14C illustrate the results for the X-direction magnetic field component obtained by subtracting the planar estimate of the noise, where FIG. 14A shows the magnetic measurement at one of the sensors, and the noise-free signal of interest, over time, FIG. 14B shows the result at the same sensor after noise removal, and the noise-free signal of interest, and FIG. 14C shows the difference in the two lines (noise free and reconstructed) of the FIG. 14B, on a different scale. As can be seen, the noise removal works well.

FIGS. 15A, 15B and 15C illustrate a fit of a quadratic spline to the data for the magnetic field component in the X-direction, where 15A, 15B and 15C correspond to times of 500, 1000 and 1500 seconds. In FIGS. 15A, 15B and 15C, the fit quadratic spline is the meshed sheet, and the specific sensor measurements are the dots.

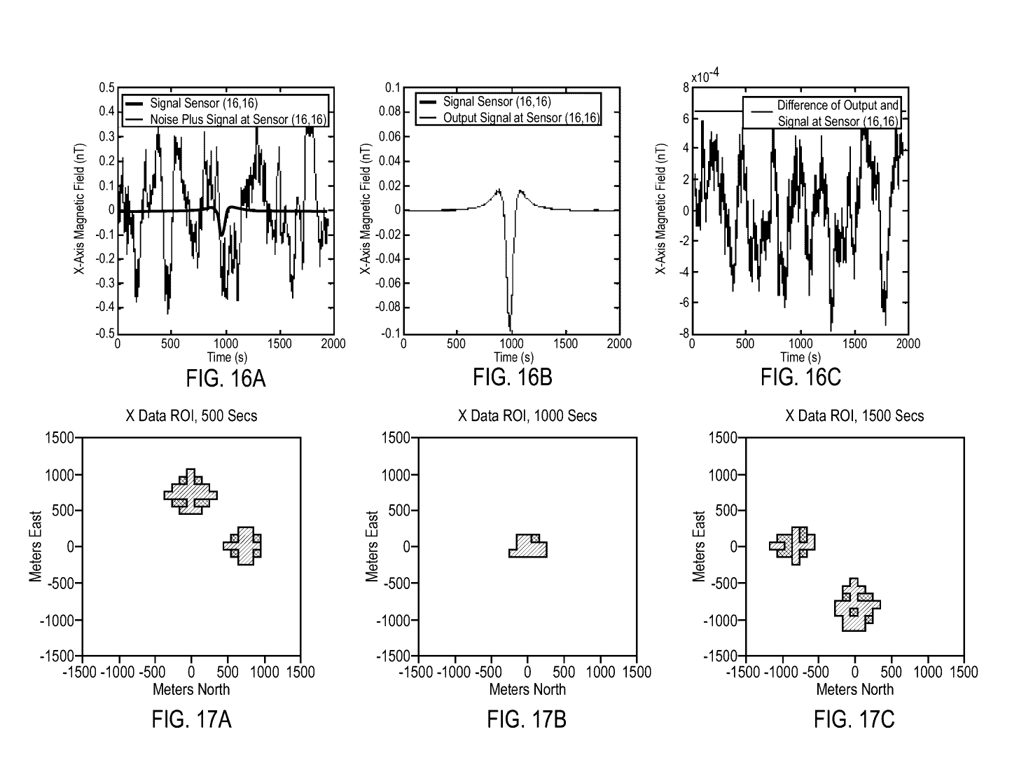

FIGS. 16A, 16B and 16C illustrate the results for the X-direction magnetic field component obtained by subtracting the quadratic spline estimate of the noise, where FIG. 16A shows the magnetic measurement at one of the sensors, and the noise-free signal of interest, over time, FIG. 16B shows the result at the same sensor after noise removal, and the noise-free signal of interest, and FIG. 16C shows the difference in the two lines (noise free and reconstructed) of the FIG. 16B, on a different scale.

Example with Two UUVs

An example with two UUVs is now described. As described with respect to FIGS. 17A, 17B and 17C, two regions of interest corresponding respectively to the two UUVs are first identified in a manner similar to that described above with respect to a single UUV. The regions of interest are then expanded using a set closing algorithm, based on dilation followed by erosion, using standard morphological image processing techniques and then taking the convex hull of the resulting region.

FIGS. 17A-17C shows the resulting regions of interest in an example for the magnetic field component in the X-direction at 500, 1000, and 1500 seconds, respectively. In each case, the lighter color region is the “core” region of interest, i.e. the values for which the measurements deviate from the array median enough to exceed the threshold. The darker color regions are the additional sensors that are included in the region of interest as a result of set closing and convex hulling of the region. As can be seen, two regions of interest a identified, each one corresponding to a different one of the two UUVs. First as can be seen, the regions of interest are first separated as shown in FIG. 17A, and then overlap in FIG. 17B, and then are separated again in FIG. 17C, suggesting that the two UUVs are moving so that one passes over the other.

Once the regions of interest are identified, they are removed, and then the rest of the data is fit, such as, for example, by fitting to a plane, or fitting to a quadratic spline. This gives a geomagnetic noise estimate that can be used in the entire region including the identified region of interest. As an alternative to fitting to a plane or aquadratic spline, a Kriging technique could be applied to the data with region of interest removed, to produce an estimate of the noise in the region of interest.

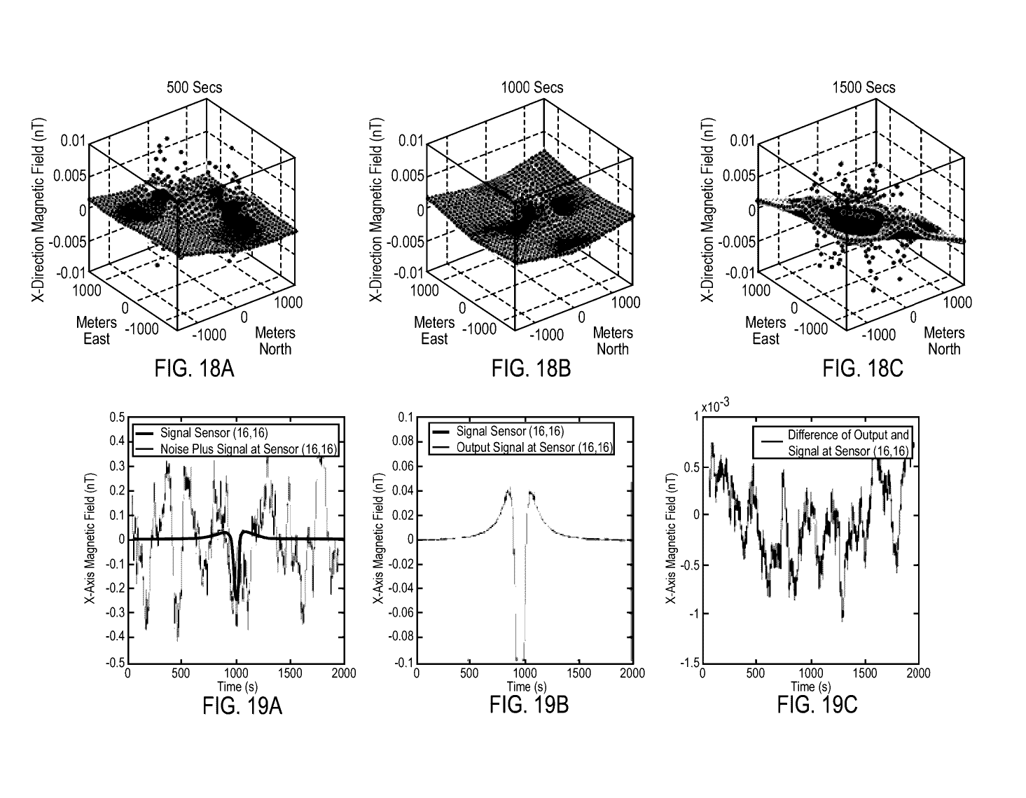

FIGS. 18A, 18B and 18C illustrate, for the two UUV case, a fit of a quadratic spline to the data for the magnetic field component in the X-direction, where 18A, 18B and 18C correspond to times of 500, 1000 and 1500 seconds. In FIGS. 18A, 18B and 18C, the fit quadratic spline is the meshed sheet, and the specific sensor measurements are the dots.

FIGS. 19A, 19B and 19C illustrate, for the two UUV case, the results for the X-direction magnetic field component obtained by subtracting the quadratic spline estimate of the noise, where FIG. 19A shows the magnetic measurement at one of the sensors, and the noise-free signal of interest, over time, FIG. 19B shows the result at the same sensor after noise removal, and the noise-free signal of interest, and FIG. 19C shows the difference in the two lines (noise free and reconstructed) of the FIG. 19B, on a different scale.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A magnetic sensor system, comprising:
a plurality of magnetic field sensors arranged in an array, each magnetic field sensor configured to measure a magnetic field at the magnetic field sensor; and
a controller configured to receive magnetic field signals from each of the plurality of magnetic field sensors so as have an array of measured magnetic field values corresponding respectively to the magnetic field sensors,
wherein the controller is configured to:
perform high pass time-domain filtering on the array of measured magnetic field values;
transform each of the measured magnetic field values to a common coordinate system to provide an array of transformed magnetic field values;
determine that a signal of interest exists in array elements of the array of transformed magnetic field values when the transformed magnetic field value deviates from spatially correlated noise by more than a predetermined threshold;
determine one or more regions of interest to be those array elements where the signal of interest exists, where for each region of interest the array elements where the signal of interest exists are adjacent to each other;
estimate a spatially correlated background noise based on the array of transformed magnetic field values; and
subtract the spatially correlated background noise from the transformed magnetic field values to provide noise removed magnetic field values.

2. The magnetic sensor system of claim 1, wherein the magnetic field sensors are diamond nitrogen vacancy magnetic field sensors.

3. The magnetic sensor system of claim 1, further comprising:
a plurality of orientation sensors, each orientation sensor corresponding to a different one of the plurality of magnetic field sensors and configured to measure a Z-direction orientation of a respective magnetic field sensor relative to the common coordinate system.

4. The magnetic sensor system of claim 3, wherein the orientation sensor is a gravity sensor.

5. The magnetic sensor system of claim 3, wherein the transforming each of the measured magnetic field values to a common coordinate system comprises rotating the measured magnetic field values based in part on the measured Z-direction orientation of the magnetic field sensor.

6. The magnetic sensor system of claim 5, wherein the rotating the measured magnetic field values comprises, for each magnetic field sensor, determining a rotation matrix based on the measured Z-direction orientation, an X-direction orientation and a Y-direction orientation of the magnetic field sensor, and taking the product of the rotation matrix with the measured magnetic field value.

7. The magnetic sensor system of claim 6, wherein the X-direction orientation is determined based on subtracting the component of the measured magnetic field value along the Z direction from the measured magnetic field value to provide a difference value, and normalizing the difference value.

8. The magnetic sensor system of claim 1, wherein the estimating a spatially correlated background noise comprises determining a median value of the transformed magnetic field values for all elements of the array of transformed magnetic field values, and setting the spatially correlated background noise as the median value.

9. The magnetic sensor system of claim 1, wherein the estimating a spatially correlated background noise comprises:
excluding the one or more regions of interest from the array of transformed magnetic field values to provide a remaining array of transformed magnetic field values;
fitting a function to the remaining array of transformed magnetic field values to provide the estimated spatially correlated background noise.

10. The magnetic sensor system of claim 9, wherein some of the magnetic field sensors are outside the one or more regions of interest.

11. The magnetic sensor system of claim 10, wherein ≧50% of the magnetic field sensors are outside the one or more regions of interest.

12. The magnetic sensor system of claim 9, wherein the function is a plane.

13. The magnetic sensor system of claim 9, wherein the function is a quadratic spline.

14. The magnetic sensor system of claim 1, wherein the determining one or more regions of interest comprises determining a core one or more regions of interest, and applying a set closing and convex hulling of the core one or more regions of interest.

15. The magnetic sensor system of claim 1, where the one or more regions of interest correspond to one or more unmanned underwater vehicles (UUVs), or ships.

16. The magnetic sensor system of claim 1, wherein the array is a one-dimensional array.

17. The magnetic sensor system of claim 1, wherein the array is a two-dimensional array.

18. A magnetic sensor system, comprising:
a plurality of magnetic field sensors arranged in an array, each magnetic field sensor configured to measure a magnetic field at the magnetic field sensor; and
a controller configured to receive magnetic field signals from each of the plurality of magnetic field sensors so as have an array of measured magnetic field values corresponding respectively to the magnetic field sensors,
wherein the controller is configured to:
transform each of the measured magnetic field values to a common coordinate system to provide an array of transformed magnetic field values;
estimate a spatially correlated background noise based on the array of transformed magnetic field values; and
subtract the spatially correlated background noise from the transformed magnetic field values to provide noise removed magnetic field values.

19. The magnetic sensor system of claim 18, wherein the magnetic field sensors are diamond nitrogen vacancy magnetic field sensors.

20. The magnetic sensor system of claim 18, further comprising:
a plurality of orientation sensors, each orientation sensor corresponding to a different one of the plurality of magnetic field sensors and configured to measure a Z-direction orientation of a respective magnetic field sensor relative to the common coordinate system.

21. The magnetic sensor system of claim 20, wherein the orientation sensor is a gravity sensor.

22. The magnetic sensor system of claim 20, wherein the transforming each of the measured magnetic field values to a common coordinate system comprises rotating the measured magnetic field values based in part on the measured Z-direction orientation of the magnetic field sensor.

23. The magnetic sensor system of claim 18, wherein the estimating a spatially correlated background noise comprises determining a median value of the transformed magnetic field values for all elements of the array of transformed magnetic field values, and setting the spatially correlated background noise as the median value.

24. The magnetic sensor system of claim 18, wherein the determining one or more regions of interest comprises determining a core one or more regions of interest, and applying a set closing and convex hulling of the core one or more regions of interest.

25. The magnetic sensor system of claim 18, wherein the array is a one-dimensional array.

26. The magnetic sensor system of claim 18, wherein the array is a two-dimensional array.

27. A magnetic sensor system, comprising:
a plurality of magnetic field sensors arranged in an array, each magnetic field sensor configured to measure a magnetic field at the magnetic field sensor; and
a controller configured to receive magnetic field signals from each of the plurality of magnetic field sensors so as have an array of measured magnetic field values corresponding respectively to the magnetic field sensors,
wherein the controller is configured to transform each of the measured magnetic field values to a common coordinate system to provide an array of transformed magnetic field values.

28. The magnetic sensor system of claim 27, wherein the magnetic field sensors are diamond nitrogen vacancy magnetic field sensors.

29. The magnetic sensor system of claim 27, further comprising:
a plurality of orientation sensors, each orientation sensor corresponding to a different one of the plurality of magnetic field sensors and configured to measure a Z-direction orientation of a respective magnetic field sensor relative to the common coordinate system.

30. The magnetic sensor system of claim 29, wherein the orientation sensor is a gravity sensor.

31. The magnetic sensor system of claim 29, wherein the transforming each of the measured magnetic field values to a common coordinate system comprises rotating the measured magnetic field values based in part on the measured Z-direction orientation of the magnetic field sensor.

32. The magnetic sensor system of claim 31, wherein the rotating the measured magnetic field values comprises, for each magnetic field sensor, determining a rotation matrix based on the measured Z-direction orientation, an X-direction orientation and a Y-direction orientation of the magnetic field sensor, and taking the product of the rotation matrix with the measured magnetic field value.

33. The magnetic sensor system of claim 32, wherein the X-direction orientation is determined based on subtracting the component of the measured magnetic field value along the Z direction from the measured magnetic field value to provide a difference value, and normalizing the difference value.

34. A magnetic sensor system, comprising:
a plurality of magnetic field sensors arranged in an array, each magnetic field sensor configured to measure a magnetic field at the magnetic field sensor; and
a controller configured to receive magnetic field signals from each of the plurality of magnetic field sensors so as have an array of measured magnetic field values corresponding respectively to the magnetic field sensors,
wherein the controller is configured to:
determine that a signal of interest exists in array elements of the array of measured magnetic field values when the measured magnetic field value deviates from spatially correlated noise by more than a predetermined threshold;
determine one or more regions of interest to be those array elements where the signal of interest exists, where for each region of interest the array elements where the signal of interest exists are adjacent to each other;
estimate a spatially correlated background noise based on the array of measured magnetic field values; and
subtract the spatially correlated background noise from the measured magnetic field values to provide noise removed magnetic field values.

35. The magnetic sensor system of claim 34, wherein the magnetic field sensors are diamond nitrogen vacancy magnetic field sensors.

36. The magnetic sensor system of claim 34, wherein the estimating a spatially correlated background noise comprises determining a median value of the measured magnetic field values for all elements of the array of measured magnetic field values, and setting the spatially correlated background noise as the median value.

37. The magnetic sensor system of claim 34, wherein the estimating a spatially correlated background noise comprises:
excluding the one or more regions of interest from the array of measured magnetic field values to provide a remaining array of measured magnetic field values;
fitting a function to the remaining array of measured magnetic field values to provide the estimated spatially correlated background noise.

38. The magnetic sensor system of claim 37, wherein the function is a plane.

39. The magnetic sensor system of claim 37, wherein the function is a quadratic spline.

40. The magnetic sensor system of claim 34, wherein the determining one or more regions of interest comprises determining a core one or more regions of interest, and applying a set closing and convex hulling of the core one or more regions of interest.

41. A magnetic sensor system, comprising:
a plurality of magnetic field sensors arranged in an array, each magnetic field sensor configured to measure a magnetic field at the magnetic field sensor; and
a controlling unit for:
receiving magnetic field signals from each of the plurality of magnetic field sensors so as have an array of measured magnetic field values corresponding respectively to the magnetic field sensors,
performing high pass time-domain filtering on the array of measured magnetic field values;
transforming each of the measured magnetic field values to a common coordinate system to provide an array of transformed magnetic field values;
determining that a signal of interest exists in array elements of the array of transformed magnetic field values when the transformed magnetic field value deviates from spatially correlated noise by more than a predetermined threshold;
determining one or more regions of interest to be those array elements where the signal of interest exists, where for each region of interest the array elements where the signal of interest exists are adjacent to each other;
estimating a spatially correlated background noise based on the array of transformed magnetic field values; and
subtracting the spatially correlated background noise from the transformed magnetic field values to provide noise removed magnetic field values.

42. A method of operating a magnetic sensor system, the magnetic sensor system having a plurality of magnetic field sensors arranged in an array, each magnetic field sensor configured to measure a magnetic field at the magnetic field sensor, the method comprising:
receiving magnetic field signals from each of the plurality of magnetic field sensors so as have an array of measured magnetic field values corresponding respectively to the magnetic field sensors;
performing high pass time-domain filtering on the array of measured magnetic field values;
transforming each of the measured magnetic field values to a common coordinate system to provide an array of transformed magnetic field values;
determining that a signal of interest exists in array elements of the array of transformed magnetic field values when the transformed magnetic field value deviates from spatially correlated noise by more than a predetermined threshold;
determining one or more regions of interest to be those array elements where the signal of interest exists, where for each region of interest the array elements where the signal of interest exists are adjacent to each other;
estimating a spatially correlated background noise based on the array of transformed magnetic field values; and
subtracting the spatially correlated background noise from the transformed magnetic field values to provide noise removed magnetic field values.

43. A method of operating a magnetic sensor system, the magnetic sensor system having a plurality of magnetic field sensors arranged in an array, each magnetic field sensor configured to measure a magnetic field at the magnetic field sensor, the method comprising:
receiving magnetic field signals from each of the plurality of magnetic field sensors so as have an array of measured magnetic field values corresponding respectively to the magnetic field sensors;
transforming each of the measured magnetic field values to a common coordinate system to provide an array of transformed magnetic field values;
estimating a spatially correlated background noise based on the array of transformed magnetic field values; and
subtracting the spatially correlated background noise from the transformed magnetic field values to provide noise removed magnetic field values.

44. A method of operating a magnetic sensor system, the magnetic sensor system having a plurality of magnetic field sensors arranged in an array, each magnetic field sensor configured to measure a magnetic field at the magnetic field sensor, the method comprising:
receiving magnetic field signals from each of the plurality of magnetic field sensors so as have an array of measured magnetic field values corresponding respectively to the magnetic field sensors; and
transforming each of the measured magnetic field values to a common coordinate system to provide an array of transformed magnetic field values.

45. A method of operating a magnetic sensor system, the magnetic sensor system having a plurality of magnetic field sensors arranged in an array, each magnetic field sensor configured to measure a magnetic field at the magnetic field sensor, the method comprising:
receiving magnetic field signals from each of the plurality of magnetic field sensors so as have an array of measured magnetic field values corresponding respectively to the magnetic field sensors;
determining that a signal of interest exists in array elements of the array of measured magnetic field values when the measured magnetic field value deviates from spatially correlated noise by more than a predetermined threshold;
determining one or more regions of interest to be those array elements where the signal of interest exists, where for each region of interest the array elements where the signal of interest exists are adjacent to each other;
estimating a spatially correlated background noise based on the array of measured magnetic field values; and
subtracting the spatially correlated background noise from the measured magnetic field values to provide noise removed magnetic field values.
